(19) United States
(12) Patent Application Publication
(10) Pub. No.: US 2007/0298536 A1
(43) Pub. Date: Dec. 27, 2007

(54) Single-crystal metal nanocrystals

(75) Inventors: Zhifeng Ren, Newton, MA (US); Wenzhong Wang, Beijing (CN)

Correspondence Address: GREENBERG TRAURIG, LLP, ONE INTERNATIONAL PLACE, 20th FL, ATTN: PATENT ADMINISTRATOR, BOSTON, MA, 02110, US

(73) Assignee: The Trustees of Boston College

(21) Appl. No.: 11/731,384

(22) Filed: Mar. 30, 2007

Related U.S. Application Data
(63) Continuation of application No. PCT/US05/35320, filed on Sep. 30, 2005.
(60) Provisional application No. 60/614,855, filed on Sep. 30, 2004.

(30) Foreign Application Priority Data
Sep. 30, 2005 (US) PCT/US05/35320

(51) Int. Cl. H01L 21/06

(52) U.S. Cl. 438/102; 257/42; 257/613; 423/1

(57) ABSTRACT

Methods for producing nanocrystals comprising metallic materials utilizing an inverse micelle solvothermal process are disclosed. Nanocrystals comprising well-ordered, single-crystalline germanium (Ge) materials with predeterminable morphologies in relatively high purity are produced by suspending a Ge salt material comprising a metal ion in a non-aqueous inverse micelle solvent comprising at least one surfactant, and introducing a reducing agent to the non-aqueous inverse micelle solvent to reduce a plurality of metal ions to form a ordered single-crystalline Ge nanocrystal.

### RELATED APPLICATIONS

This application is a continuation of PCT International Patent Application Number PCT/US2005/035320, filed Sep. 30, 2005, which claims the benefit of U.S. Provisional Application Ser. No. 60/614,855, filed Sep. 30, 2004, and the entirety of these applications are hereby incorporated herein by reference for the teachings therein.

### GOVERNMENT SUPPORT

The present invention was made with partial support from NASA (Grant No. 5000486). The Government has certain rights in the invention.

### FIELD

The presently disclosed embodiments relate generally to methods for producing single-crystal nanocrystals comprising metallic material utilizing an inverse micelle solvothermal process, and more particularly to methods for producing nanocrystals comprising substantially pure ordered, single-crystalline semiconducting metallic materials with predetermined morphology in relatively high yields.

### BACKGROUND

Metal nanocrystals are widely used as catalysts, and are increasingly being explored as materials for potential single electron devices, self-assembled monolayers, and thin film precursors. Nanocrystalline semiconducting materials such as silicon (Si) and germanium (Ge) have attracted much interest because of their visible photoluminescence at ambient temperature and their potential for incorporation in electronic and optoelectronic devices.

Flash EEPROM (Electrically Erasable and Programmable Read Only Memory) are presently one of the most popular forms of non-volatile memories. Conventionally, increased data-retention time can be achieved by increasing the tunnel oxide thickness of these devices, however, thick tunnel oxides hinders the write and erase speeds of these devices. Memory cells containing nanocrystals embedded within the gate dielectric have been demonstrated to improve on the performance limitation of a conventional floating gate device. Replacing a conventional floating gate with nanocrystals has the advantages of low programming voltages and improved retention time. The syntheses of nanocrystals within the gate dielectric have been demonstrated in the form of silicon, germanium or tin nanocrystals formed through the ion implantation technique. However, there exist limitations in the ion implantation technique including the minimal requirement for the control (cap) oxide thickness and also the possibility of degrading the tunnel oxide quality throughout the implantation process.

Preparative methods known in the art for monodisperse particles of transition metal catalysts such as Pt, Pd, Rh and Ir from the corresponding halides involving reduction of metal salts from microemulsions in aqueous solutions containing a surfactant have been modified for synthesis of the group III metal indium (In) as nanocrystals (P. Sinha and G. S. Collins, Nanostructured Materials, Vol. 3, 217-224 (1993)). However, the process results in inhomogeneous metal clusters and requires a large excess of hydride reducing agent to effect the reduction of the indium halide salt largely due to decomposition of the hydride reducing agent in an aqueous medium. The prior art also discloses the synthesis of germanium nanocrystals as metal nanoclusters by reduction of germanium halides (GeX₄) in inverse micelles. (Wilcoxon et al., Physical Review B, Vol. 64, 035417-1-035417-9, (2001)). The Wilcoxon et al. method describes a method for obtaining germanium nanocrystals of varied sizes containing germanium clusters, that are purified and size separated by high-pressure liquid chromatography (HPLC). The Wilcoxon et al. method is, therefore, unsuited to obtain single-crystal metal nanocrystals of uniform crystalline shape and crystal size. Prior art methods for forming germanium nanocrystals include, for example, solidification of germanium (Ge) or germanium dioxide (GeO₂) in the molten state in an inert atmosphere by either rapid or slow cooling to ambient temperature. Other conventional methods disclosed for preparation of Ge nanocrystals include gas evaporation, gas condensation, thermal evaporation, molecular beam epitaxy, pulsed laser ablation and Sol-Gel formation and cluster deposition in vacuum. Additional methods in the art include the reactions of germanium Zintl salts with germanium halides and reduction of germanium halides by sodium naphthalenide or anhydrous metal hydrides. Such methods, however, are limited by low yields of Ge nanocrystals, that make them impractical for industrial scale preparation, which renders the full characterization of structural aspects difficult, thereby resulting in limiting their processability for use in device applications.

Although solution-phase synthesis of free-standing colloidal nanocrystals of transition metals and group III metals such as indium have been attempted, the synthesis nanocrystals of group IV semiconducting metals such as Si and Ge have been particularly problematic primarily due to their strong covalent bonding, which necessitates the use of high temperature environments to promote crystallization. Therefore, there exists a need for new methods for the synthesis of Ge nanocrystals in high yield that are economical and efficient under relatively milder conditions, readily scalable for industrial scale preparations (gram and kilogram quantities) that would enable their nanocrystal characterization and improve their processability, and thereby enable their integration into working devices.

### SUMMARY

The presently disclosed embodiments relate generally to methods to prepare single-crystal nanocrystals of semiconductor metallic material under mild conditions with high purity and in relatively high yields. In particular, the presently disclosed embodiments relate to methods for producing nanocrystals of Group IV semiconducting metallic material, that are substantially pure, ordered, single-crystalline and have predeterminable crystal shape, size and morphology. The presently disclosed embodiments overcome the limitations of prior art processes by enabling the synthesis of metallic nanocrystals in a single crystal form, and having a substantially uniform size and shape. No additional purification or size separation steps are therefore, required. Unlike the metal cluster nanocrystals known in the art, the single crystal nanocrystals of presently disclosed embodiments are likely to have fewer crystalline defects and substantially lower trapped impurities, thereby conferring on them superior optoelectronic, electronic and electrical properties that are important for use in electronic applications.

The presently disclosed embodiments utilize an inverse micelle process that involves reduction of a semiconducting metal salt suspended in a non-aqueous inverse micelle solvent comprising a surfactant to the corresponding metal, whereby the metal assumes an ordered single-crystalline nanocrystal morphology.

The synthetic process for obtaining single-crystalline nanocrystalline semiconducting metallic materials involves suspending a metallic salt material comprising a metal ion in a non-aqueous inverse micelle solvent comprising at least one surfactant, and introducing a reducing agent to the non-aqueous inverse micelle solvent to reduce a plurality of metal ions to form metal nanocrystals. Optionally, the surfactant is chosen to impart predeterminability of the morphology and shape on the metal nanocrystal.

According to aspects illustrated herein, there is provided a process of producing micro-scale single-crystalline nanocrystalline semiconducting metal nanocrystals, in particular, germanium nanocrystals (Ge nanocrystals) utilizing an inverse micelle solvothermal process at relatively low temperature.

According to aspects illustrated herein, there is provided a process of producing semiconducting metal nanocrystals with substantially high purity and ordered crystal morphology, utilizing an inverse micelle solvothermal process at relatively low temperature.

According to aspects illustrated herein, there is provided a process of producing single-crystalline germanium (Ge) nanocrystals having predeterminable morphologies utilizing an inverse micelle solvothermal process at relatively low temperature.

According to aspects illustrated herein, there is provided a process for producing ordered single-crystalline semiconducting metal nanocrystals with predetermined morphology involves reduction of halide salts of a semiconducting metal in a non-aqueous inverse micelle solvent with an alkali metal, alkali metal hydride or a hydrazine reducing agent using a surfactant as capping agent and shape controlling agent. Nanocrystals with predeterminable morphologies including, but not limited to, nanosphere, nanocube, hexagonal, triangular and similar morphologies are produced by varying the growth parameters, such as the concentration and type of the surfactant.

According to aspects illustrated herein, ordered single-crystalline Ge nanocrystals are prepared in gram quantities by reducing a germanium salt such as germanium tetrachloride (GeCl₄) in a non-aqueous solvent such as hexane with a reducing agent such as sodium metal. Ordered single-crystalline Ge nanocrystals comprising substantially pure Ge with diamond-like phase structure, with high crystallinity are obtained by the process of the presently disclosed embodiments.

According to aspects illustrated herein, ordered single-crystalline Ge nanocubes are prepared by reducing a germanium salt such as germanium tetrachloride (GeCl₄) in a non-aqueous solvent such as hexane with a reducing agent such as sodium metal and C₁₂E₇ as a capping agent.

According to aspects illustrated herein, ordered single-crystalline Ge nanospheres are prepared by reducing a germanium salt such as germanium tetrachloride (GeCl₄) in a non-aqueous solvent such as hexane with a reducing agent such as sodium metal and C₁₂E₅ as a capping agent.

The solution phase size-selective synthetic methods can be used to prepare substantially uniform semiconductor metal nanocrystals, whose crystal size is controllable from 1 to 200 nm. Preparation of uniform nanocrystals enables systematic characterization of the structural, electronic, and optical properties of materials as they evolve from molecular to bulk in the nanometer size range. Sample uniformity makes it possible to manipulate nanocrystals into close-packed, glassy, and ordered nanocrystal assemblies (superlattices, colloidal crystals, supercrystals, etc.). Extensive structural characterization, which is critical to understanding the electronic and optical properties of both nanocrystals and their assemblies, can therefore be accomplished by the process of the presently disclosed embodiments. For example, at inter-particle separations of 5-100 Å, dipole-dipole interactions lead to energy transfer between neighboring nanocrystals, and electronic tunneling between proximal nanocrystals giving rise to dark current and photoconductivity. At separations of <5 Å, exchange interactions cause otherwise insulating assemblies to become semiconducting, metallic, or superconducting depending on nanocrystal composition. Nanocrystal solid-state materials with optimal properties can be obtained by tailoring the size and composition of nanocrystals and the length and electronic structure of the matrix.

The presently disclosed embodiments offers several advantages over currently known methods for producing nanocrystals of semiconducting metallic materials. The methods of the presently disclosed embodiments for producing ordered single-crystalline metal nanocrystals utilizing a relatively lower temperature inverse micelle solvothermal process is simple, mild and reproducible with high yields, making it suitable for commercial applications in industrial production of ordered single crystal metal nanocrystals. By utilizing non-aqueous conditions, the inverse micelle solvothermal process of the presently disclosed embodiments produces nanocrystals that are homogeneous and reduces the need for an large excess of reducing agent.

The process of the presently disclosed embodiments utilizes conventional reactor equipment that is readily amenable to scale up, thereby making it economically and commercially viable. The ordered single-crystalline germanium (Ge) nanocrystals produced by the inverse micelle solvothermal process are highly crystalline and are synthesized in different morphologies that are predeterminable. These nanocrystals with predeterminable morphologies are obtained directly without requiring additional, post-synthetic steps, thereby enabling them to be subsequently processed and integrated into electronic and optoelectronic devices.

### BRIEF DESCRIPTION OF THE DRAWINGS

FIG. 1 shows an XRD spectrum of the Ge nanocrystals prepared by a low temperature inverse micelle solvothermal route.

FIG. 2 shows depictions of Ge nanocrystals. FIG. 2(a) shows a TEM image of the as-prepared Ge nanocrystals. FIG. 2(b) shows a SAED pattern of a 25 nanometers (nm) Ge nanocrystal. FIG. 2(c) shows an HRTEM image of spherical Ge nanocrystals. FIG. 2(d) shows an HRTEM image of triangular Ge nanocrystals.

FIG. 3 shows an XRD pattern of the as-prepared Ge nanospheres (280° C. with C₁₂E₅ as the capping agent).

FIG. 4 shows depictions of spherical Ge nanocrystals. FIG. 4(a) shows a TEM image of spherical Ge nanocrystals prepared at low concentration of surfactant C₁₂E₅. FIG. 4(b) shows an SAED pattern of a spherical nanocrystal with a diameter of 20 nm. FIG. 4(c) shows an HRTEM image of a Ge nanosphere with diameter of 15 nm. FIG. 4(d) shows an EDS spectrum obtained from the as-prepared Ge nanospherical nanocrystals. FIG. 4(e) shows a TEM image of spherical Ge nanocrystals.

FIG. 5 shows low magnification (FIG. 5(a)) and medium magnification (FIG. 5(b)) TEM images of the Ge nanospheres. FIG. 5(c) shows a SAED pattern of a 20 nm Ge nanosphere. FIG. 5(d) shows a diameter distribution histogram of the Ge nanosphere.

FIG. 6 shows depictions of Ge nanospheres. FIG. 6(a) shows HRTEM images of a spherical Ge nanocrystal. FIG. 6(b) shows a Ge nanocrystal with a twinning boundary (indicated by an arrow). FIG. 6(c) shows a Ge nanocrystal with zigzag-twinning boundaries (indicated by arrows). FIG. 6(d) shows an EDS spectrum of the as-prepared crystalline Ge nanospheres.

FIG. 7 shows an XRD pattern of the as-prepared Ge nanocubes.

FIG. 8 shows depictions of Ge nanocubes. FIG. 8(a) shows a TEM image of the Ge nanocubes prepared by using surfactant C₁₂E₇ as a capping agent. FIG. 8(b) shows a HRTEM image of a Ge nanocube. FIG. 8(c) shows an EDS spectrum taken from the as-prepared Ge nanocubes.

FIG. 9(a) shows an HRTEM image of a Ge nanocube, indicating the nanocube is probably composed of four small cubes. FIG. 9(b) shows a TEM image of the Ge nanocubes showing the surface contrast changes and melting process.

FIG. 10 shows a scheme depicting the growth process of the nanocubes.

FIG. 11 shows XRD patterns of the as-prepared Ge nanocrystals. FIG. 11(a) shows Ge nanocrystals prepared using surfactant C₁₂E₅ (high concentration) as a capping agent. FIG. 11(b) shows Ge nanocrystals prepared using surfactant C₁₂E₅ (low concentration) as a capping agent. FIG. 11(c) shows Ge nanocrystals prepared using surfactant Cl₂E₇ (high concentration) as a capping agent. FIG. 11(d) shows a diameter distribution histogram of the Ge nanocrystals.

### DETAILED DESCRIPTION

The presently disclosed embodiments provide a reductive synthesis of a metal nanocrystal from a metallic salt under mild conditions with high yield and high purity, by suspending the metallic salt material comprising a metal ion in a non-aqueous inverse micelle solvent comprising at least one surfactant, and introducing a reducing agent to the non-aqueous inverse micelle solvent to reduce a plurality of metal ions to form the metal nanocrystal. In particular, the presently disclosed embodiments relate to methods comprising an inverse micelle solvothermal process for producing nanocrystals of Group IV semiconducting metallic material that are substantially pure, well-ordered, single-crystalline and have predeterminable crystal morphologies.

The inverse micelle process comprises the steps of suspending a semiconducting metal salt in a non-aqueous inverse micelle solvent comprising at least one surfactant and reducing the semiconducting metal salt to the corresponding metal wherein the metal assumes an ordered single-crystalline nanocrystal morphology.

Without wishing to be bound by theory, it is believed upon mixing a semiconducting metal salt, a surfactant, a non-aqueous inverse micelle solvent and a reducing agent, inverse micelles are formed and ordered single-crystalline nanocrystals comprising semiconducting material are formed within the inverse micelles in situ upon reduction of the semiconducting metal salt under solvothermal reaction conditions.

An “inverse micelle solvent” as used herein refers to a solvent capable of forming an inverse micelle. Preferably the inverse micelle solvent is a non-aqueous inverse micelle solvent. Typically, a non-aqueous inverse micelle solvent is a non-polar solvent. Examples of inverse micelle solvents include, but are not limited to, hexane, petroleum ether, toluene, decane. In a currently preferred embodiment, the non-aqueous inverse micelle solvent is hexane.

The nanocrystal size in the process is controlled by micellar size. Surfactants utilized perform the function of a capping agent. Capping molecules on the surface of resulting nanocrystals prevent individual nanocrystals from aggregation and hence increasing nanocrystal solubility. In addition, the concentration of the capping molecules serves as an adjustable factor to control the size of the resulting nanocrystals.

In an embodiment, the surfactant is a non-ionic organic surfactant, such as polyethylene glycol (PEG). In a currently preferred embodiment, the surfactant is pentaethylene glycol ether (Cl₂E₅). In a currently preferred embodiment, the surfactant is heptaethylene glycol ether (Cl₂E₇). Anionic surfactants, such as sodium dodecyl sulfate (SDS), sodium di(2-ethylhexyl) sulfosuccinate (AOT) may be used. Cationic surfactants, such as cetyltrimethylammonium bromide (CTAB) may be used. The surfactant is chosen appropriately to predetermine nanocrystal size.

The inverse micelle process may be performed under solvothermal conditions using a suitable reactor. Suitable reactors include those capable of autogenus pressure at elevated temperatures. Preferred examples of suitable reactors include, but are not limited to, Parr-type closed hydrogenation reactors.

The reducing agents utilized are those having an electrochemical potential sufficient to effect reduction of a metal ion from its positive oxidation state to the metallic (zero oxidation) state, or produce the corresponding metal hydrides that, in turn, reduce to zero oxidation state metals. A reducing agent operative herein may be a hydride (H⁻) transfer reagent or have an electrochemical potential greater than the reduction potential of the metal ion to be reduced. The result of metal ion reduction within an inverse micelle is the formation of a metal nanocrystal. Preferably, reducing agents utilized are those capable of reducing semiconductor metallic salts to semiconducting metal. In an embodiment, the reducing agent is selected from the group consisting of: hydrogen gas (H₂), zinc metal (Zn), aluminum metal (Al), lithium aluminum hydride (LiAlH₄), sodium borohydride (NaBH₄) and hydrazine (H₂NNH₂). In an embodiment, the reducing agent is an alkali metal such as lithium metal (Li), sodium metal (Na) or potassium metal (K), or an alkaline earth metal such as magnesium metal (Mg), or calcium metal (Ca). In a currently preferred embodiment, the reducing agent is (Na). The reducing agent is preferably used in the form of a dispersion in a solvent such as toluene.

The process of the presently disclosed embodiments can be used to obtain nanocrystals of semiconducting metallic materials. The term “semiconducting metallic material” or “semiconducting material” is afforded the meaning generally referred to in the art. In an embodiment, a nanocrystal of semiconducting metallic material is formed of a semiconducting material including, but not limited to, silicon (Si), germanium (Ge), gallium (Ga), indium (In), tin (Sn), carbon (C), tellurium (Te), gadolinium (Gd), neptunium (Np), GaAs, GaN, CdS, CdSe, CdTe, CdMnS, PbTe, PbSe, Bi₂Te₃ or Bi₂Se₃. In an embodiment, the semiconducting material comprises an element selected from any of groups III, IV, V or VI of the periodic table of the elements. In a currently preferred embodiment, the semiconducting material is a group IV element such as silicon (Si) or germanium (Ge). In a currently preferred embodiment the semiconducting material is germanium (Ge).

The metallic salt material comprises molecules of a metal salt compound comprising a metal ion that is associated with one or more counterions. The molecules that comprise the metallic salt may additionally contain one or more organic ligands.

A “semiconductor metal salt” as used herein comprises an ionic semiconductor metal and a counter ion. Semiconductor metal salts optionally include organometallic complexes containing one or more organic ligands. Examples of semiconducting metal salts and organometallic complexes include, but are not limited to, GeCl₄, phenyl-GeCl₃, SiCl₄, and RSiCl₃ (R═H, octyl) or hydrates, mixtures or combinations thereof. In a currently preferred embodiment the semiconducting metal salt comprises chlorogermaniums such as GeCl₄ or phenyl-GeCl₃.

A semiconductor metal salt, is chosen as the source of metal ions for reduction to form a nanocrystal. In an embodiment, the semiconductor metal salts are inorganic metallic salts. Metal ion counter anions operative herein illustratively include, but are not limited to, halides, such as fluoride, chloride, bromide; iodide; nitrate; phosphate; perchlorate; formate; acetate; borate; hydroxide; silicate; carbonate; sulfite; sulfate; nitrite; phosphite; or hydrates, mixtures or combinations thereof. A metallic salt may be used alone, in combination with one or more other metallic salts, or in combination with an organometallic complex comprising the same metal. Examples of organometallic complexes include, but are not limited to, phenyl-GeCl₃.

In an embodiment, a method of producing ordered single-crystalline semiconductor metal nanocrystals utilizes an inverse micelle solvothermal process at relatively lower temperatures in comparison to conventional methods.

In an embodiment, the process for preparing ordered single-crystalline nanocrystals of semiconducting metallic material comprises mixing a semiconducting metal salt, a reducing agent and a surfactant in a non-aqueous inverse micelle solvent, and heating the mixture under solvothermal conditions.

In an embodiment, ordered single-crystalline Ge nanocrystals are produced by mixing a germanium salt such as GeCl₄ or phenyl-GeCl₃, a surfactant utilized as a capping agent such as pentaethylene glycol ether (C₁₂E₅) or heptaethylene glycol ether (C₁₂E₇) and a alkali metal dispersion such as a Na dispersion utilized as a reducing agent, in a non-polar solvent. The mixture is then transferred to autogenus pressure reactor and heated.

In a currently preferred embodiment, ordered single crystal Ge nanocrystals are prepared by combining 80 mL hexane, 0.6 mL GeCl₄, 0.6 mL phenyl-GeCl₃, 1.8 mL Cl₂E₅, and 5.6 mL Na (25 wt % dispersion in toluene) into a 200 mL flask followed by stirring the mixture with a magnetic stirrer for 30 minutes before transferring the mixture to a 125 mL Parr reactor (Model 4750, Parr Company, Moline, Ill.). Once the mixture is added to the Parr reactor, the Parr reactor is kept at 280° C. for 72 hours in a furnace, and then cooled to room temperature. A black powder is then collected and washed with excess amounts of hexane, alcohol, and distilled water to remove NaCl byproduct and hydrocarbon residue, and then dried at 60° C. for 12 hours in a vacuum oven to give the ordered single crystal Ge nanocrystals.

The inverse micelle solvothermal process utilized in the methods may be performed at a relatively low temperature compared to conventional methods which are typically the melt temperatures of the semiconducting metal. In an embodiment, the inverse micelle solvothermal process is performed at a temperature below that of the supercritical temperature of the solvent utilized in forming the inverse micelles. In an embodiment, the inverse micelle solvothermal process is performed at a temperature ranging from about 50° C. to about 500° C. In a currently preferred embodiment, the inverse micelle solvothermal process is performed at a temperature of about 280° C.

The method may produce ordered single-crystalline Ge nanocrystals in relatively high yields. Typically the ordered single-crystalline Ge nanocrystals may be produced in gram quantities from a single reaction. The process utilizes conventional reactor equipment that is readily amenable to scale up, thereby making it economically and commercially viable.

As used herein, the term “nanocrystal” defines a crystalline domain having dimensions along at least one axis ranging from about 1 nanometer (nm) to about 1 micrometer (μm). The nanocrystals produced by the method typically range in dimensions from about 1 to about 200 mm. In an embodiment, the nanocrystals range in size from about 15 to 25 mm. In a currently preferred embodiment, nanospheres have an average diameter of about 20 nm. In a currently preferred embodiment, nanocubes have an average edge length of about 100±20 nm.

In an embodiment, a method of producing nanocrystals of semiconducting material that are substantially pure and well-ordered, uses a low temperature inverse micelle solvothermal process.

In an embodiment, a method produces well-ordered single-crystalline Ge nanocrystals. A “well-ordered” or “ordered” nanocrystal as used herein refers to a homogeneous crystal structure substantially free of amorphous material or other impurities. In a currently preferred embodiment, the Ge nanocrystals have a diamond cubic structure. In a currently preferred embodiment, the Ge nanocrystals comprise single phase Ge.

In an embodiment a method produces substantially pure single-crystalline metal nanocrystals. A substantially pure single-crystalline metal nanocrystal typically comprises about 90 to about 100% weight/weight sample, and preferably is over about 99% pure but, may be specified as any integer of percent between 90 and 100. In a currently preferred embodiment, the substantially pure single-crystalline metal nanocrystals are at least about 95%, 96%, 97%, 98%, 99% or 100% pure.

The physical characteristics of the ordered single-crystalline nanocrystals such as crystal morphology, shape and size may be observed by means including, but not limited to, transmission electron microscopy (TEM), selected area electron diffraction (SAED), high resolution transmission electron microscopy (HRTEM) and X-ray diffraction (XRD).

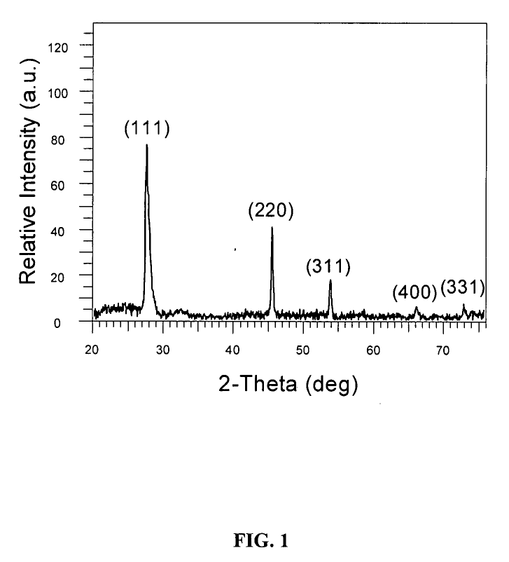

FIG. 1 shows the X-ray diffraction (XRD) spectrum of the prepared Ge nanocrystals that exhibits strong crystalline peaks that may be completely indexed to the standard diamond-phase Ge, not only in peak position, but also in relative intensity. The Ge lattice constant obtained by refinement of the XRD data of the nanocrystals is a=5.648 Å, which is consistent with that of the bulk Ge. (JCPDS No. 4-545, Fd3m, a=5.657 Å).

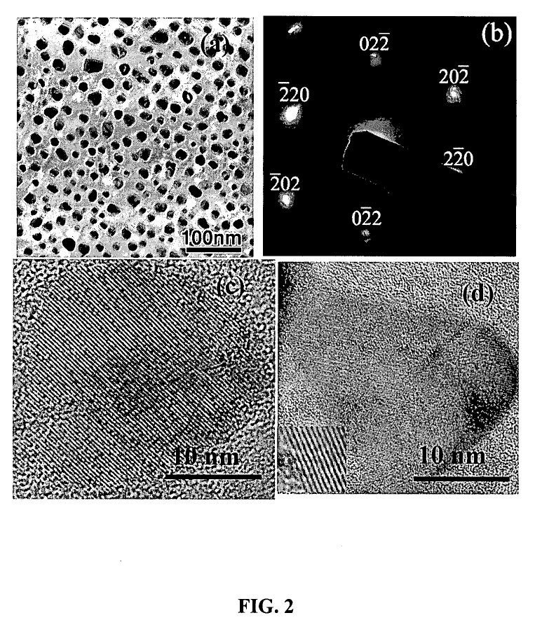

FIG. 2(a) is a representative TEM image of the Ge nanocrystals. The as-prepared Ge nanocrystals are a mixture of different shapes including sphere, triangle, cube, hexagon, and similar shapes. FIG. 2(b) shows a selected area electron diffraction (SAED) pattern obtained from a 25 nm diameter nanocrystal, exhibiting the characteristic spot pattern of a single crystal domain and hexagonal symmetry of {111} lattice plane of Ge. The SAED pattern may be indexed based on a cubic cell with lattice parameter a=5.657 Å, consistent with the XRD results. FIGS. 2(c) and 2(d) show high resolution transmission electron microscopy (HRTEM) images of the as-prepared Ge nanocrystals. The HRTEM images illustrate that these nanocrystals are high quality single-crystalline Ge with diamond cubic structure. The interplanar distance of the sphere-shaped nanocrystals (FIG. 2(c)) is 3.24 Å, consistent with the known value of the {111} planes of diamond cubic Ge. FIG. 2(d) is the HRTEM image of triangle-shaped nanocrystals (The inset is an enlarged HRTEM image). In triangular nanocrystals, the lattice distance is 3.22 Å, corresponding to the {111} planes of the diamond cubic Ge.

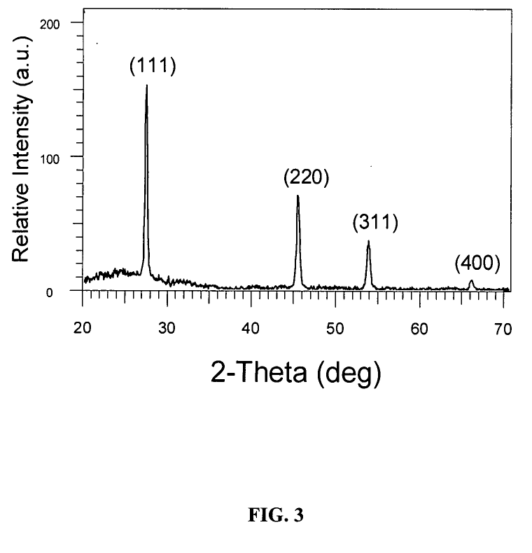

FIG. 3 shows an XRD pattern of the as-prepared Ge nanospheres (280° C. with C₁₂E₅ as the capping agent).

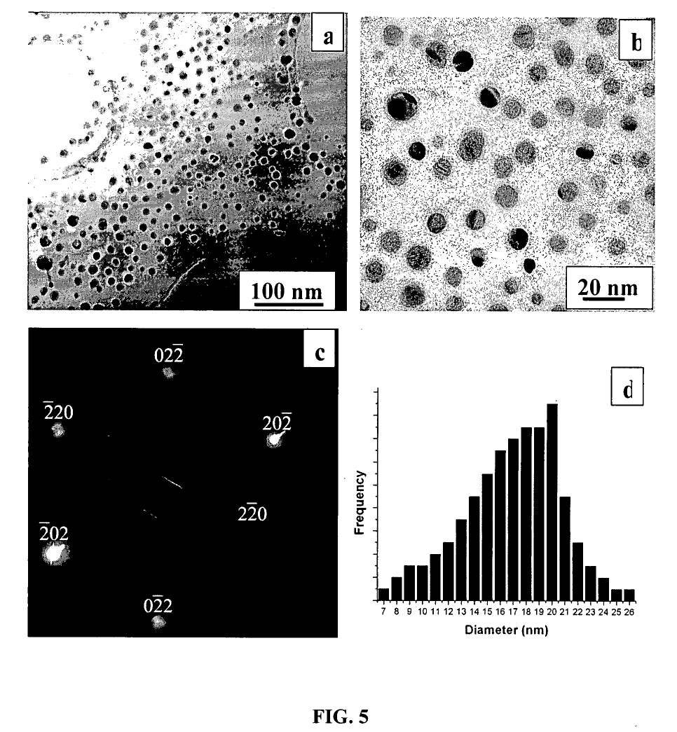

FIG. 5(a) shows a low magnification TEM image and FIG. 5(b) shows a medium magnification TEM image of the as-prepared Ge nanocrystals, respectively. The average diameter obtained from the TEM images is about 19 nm. FIG. 5(c) shows a SAED pattern of a 20 nm Ge nanosphere.

To determine the size distribution of the as-prepared nanocrystals, the nanoscystals were studied under HRTEM on many areas. FIG. 5(d) shows the histogram revealing the diameter distribution of the Ge nanospheres ranging from 7 to 26 nm with the largest percentage (80%) in the range of 14 to 21 nm. The average diameter calculated from the histogram is 19 nm.

TABLE 1
Summary of the main diffraction peak positions and intensities of the Ge
nanocrystals and the standard values (JCPDS No. 4-545).

| | | Angle (20°) | | | |
|---|---|---|---|---|---|
| | | 27.5 | 45.5 | 53.9 | 66.2 |
| d value (Å) | Present Invention | 3.237 | 1.992 | 1.700 | 1.410 |
| | Standard | 3.266 | 2.000 | 1.706 | 1.414 |
| Intensity (%) | (JCPDS No. 4-545) | 199 | 53 | 23 | 7 |
| | Present Invention | | | | |
| | Standard | 100 | 57 | 39 | 7 |

In an embodiment, a method produces ordered single-crystalline semiconductor metal nanocrystals having predeterminable morphologies using a low-temperature inverse micelle solvothermal process.

The ordered single-crystalline semiconductor metal nanocrystals produced by the methods of the presently disclosed embodiments may have various macroscopic morphologies or shapes. The semiconductor metal nanocrystals may be spherical, cubic, triangular, pyramidal, hexagonal, or rod- and wire-shaped and can be tuned by adjusting the crystal growth parameters appropriately.

The shape of the ordered single-crystalline semiconductor metal nanocrystals can be predetermined by appropriate choice of the type of surfactant capping agent, and by varying its concentration. In an embodiment, the surfactant is pentaethylene glycol ether (Cl₂E₅). In an embodiment, the surfactant is heptaethylene glycol ether (Cl₂E₇).

For example, when the amount of surfactant of Cl₂E₅ was decreased from 1.8 mL to 0.6 mL with other experimental conditions as described hereinabove are unchanged, single crystal spherical Ge nanocrystals are synthesized. When the surfactant C₁₂E₇ is used as a capping agent (1.8 mL) with other experimental conditions as described hereinabove unchanged, Ge nanocubes are prepared.

Without wishing to be bound by theory, the concentration of surfactant appears to effect the shape of the metal nanocrystals. The shapes of micelles formed by surfactant such as, for example, C₁₂E₅ in hexane solvents, determines the nanocrystal shape.

Without wishing to be bound by theory, it is also believed that the selective adsorption of surfactant molecules and their respective counterions on certain crystallographic facets during particle growth effect the formation of nanocrystals with featured shapes.

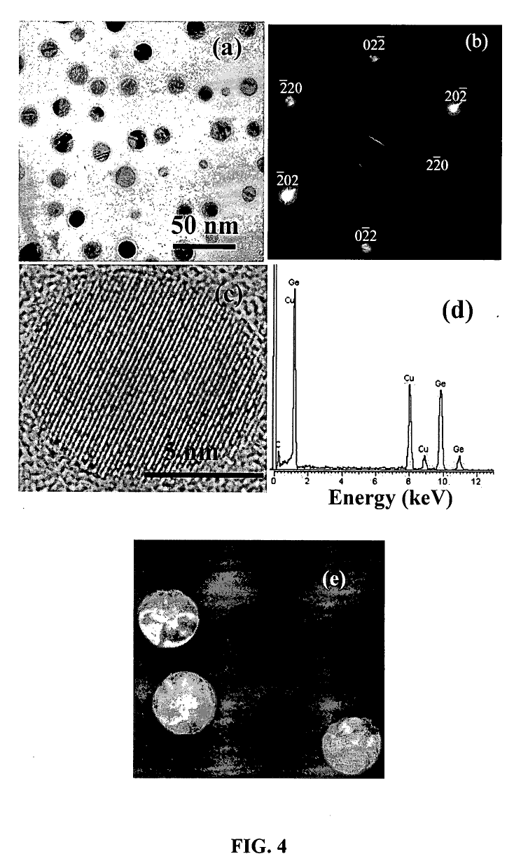

FIG. 4 shows depictions of spherical Ge nanocrystals. FIG. 4(a) is a TEM image showing that the sphere-shaped nanocrystals have uniform shape with an average diameter of 20 nm. The SAED pattern taken from a nanosphere with a diameter of 20 nm also exhibits the spot pattern and the hexagonal symmetry of the {111} lattice plane of Ge, indicating a highly crystalline diamond cubic structure (FIG. 4(b)). The HRTEM image shows that the Ge nanosphere with a diameter of 15 nm is high quality single-crystalline with interplanar distance of 3.26 Å, which is consistent with the value (3.266 Å) of the {111} planes of diamond cubic structure Ge (FIG. 4(c)). FIG. 4(d) shows an energy-dispersive X-ray spectroscopy (EDS) spectrum obtained from a selected area of the Ge nanocrystals. The EDS spectrum illustrates that the as-prepared nanocrystals are composed of pure Ge. The peaks of copper (Cu) and carbon (C) come from copper grid and carbon film. FIG. 4(e) shows a TEM image of spherical Ge nanocrystals.

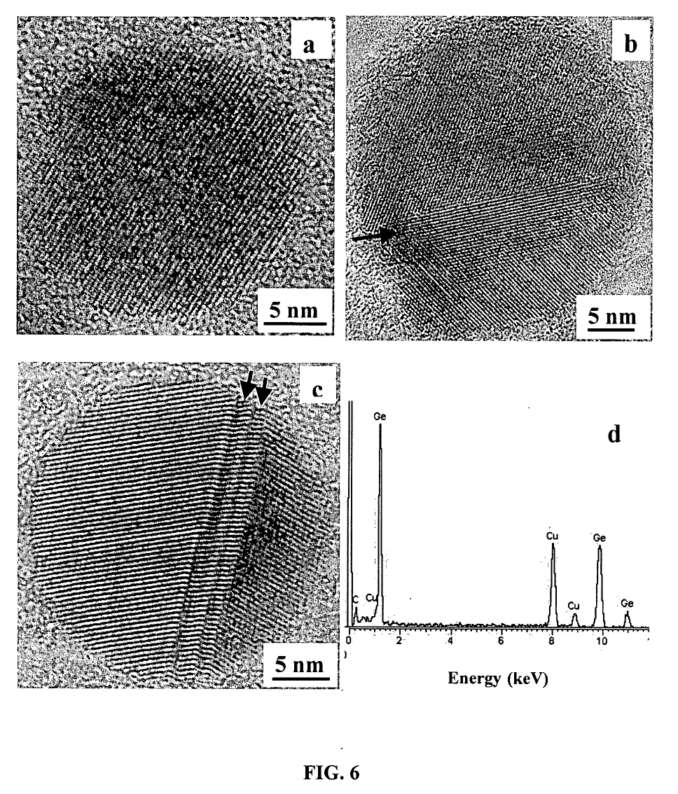

FIG. 6 shows depictions of Ge nanospheres. FIG. 6(a) shows HRTEM images of a spherical Ge nanocrystal. Note that there exist twin boundaries in some Ge nanocrystals as shown in FIG. 6(b) and FIG. 6(c) indicated by the arrows. FIG. 6(c) shows an HRTEM image of a spherical Ge nanocrystal with zigzag-twinning structure. HRTEM images illustrate that the two twinned nanocrystals have the same twinning plane {111}. It has been reported that twinning is frequently observed in face-centered cubic (fcc) nanocrystals. Twinning is the result of two subgrains sharing a common crystallographic plane. Note that twinning may play an important role in phonon scattering, but transparent to electron transport, which is much desired for good thermoelectric materials. FIG. 6(d) shows an EDS spectrum of the as-prepared crystalline Ge nanospheres.

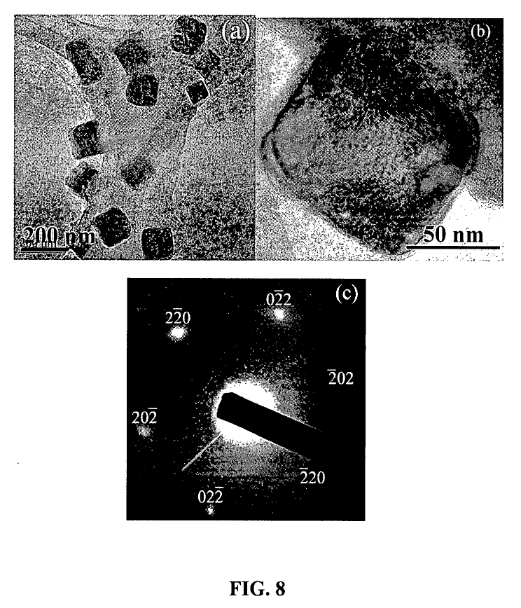

FIG. 8(a), FIG. 8(b), and FIG. 8(c) are TEM, HRTEM and EDS images of the Ge nanocubes prepared by using surfactant C₁₂E₇ as a capping agent, respectively. The TEM image indicates that the nanocrystals prepared by using C₁₂E₇ as a capping agent have cubic morphology with an edge length of 100±20 nm. The SAED and HRTEM results show that the Ge nanocubes are single crystals with diamond cubic structure. The EDS spectrum shows that the prepared Ge nanocubes are composed of single phase Ge.

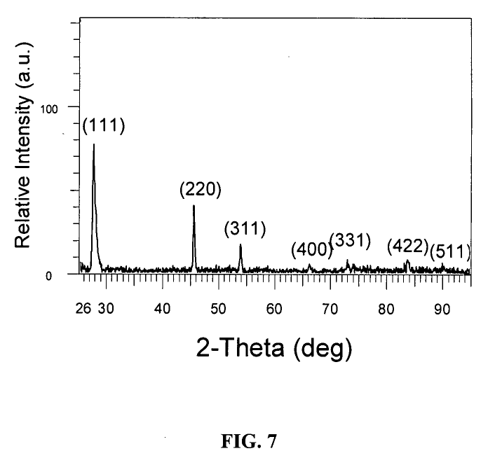

FIG. 7 is the XRD pattern of the as-prepared Ge nanocrystal powder. The XRD spectrum undisputedly exhibits strong and clear characteristic crystalline peaks of the pure diamond-type Ge. Refinement of the XRD data shows that the lattice constant of the Ge nanocrystals is a=5.655 Å, which is consistent with that (a=5.657 Å) of the bulk Ge (JCPDS No. 4-545, Fd3m).

FIG. 8(a) shows a representative low magnification TEM image of the Ge nanocubes. The TEM image reveals that the Ge nanocrystals prepared using surfactant C₁₂E₇ as a shape controlling agent have cubic morphology. A careful TEM survey of the nanocubes from different areas on the copper grid indicates that most of the nanocubes are uniform in shape and size, with an edge length of 100±20 nm. Some small size nanocubes were also observed. FIG. 8(b) shows a TEM image of an individual nanocube and FIG. 8(c) shows the corresponding SAED pattern that exhibits the hexagonal symmetry of the {111} lattice plane of diamond-type Ge, indicating the high crystallinity of the nanocubes.

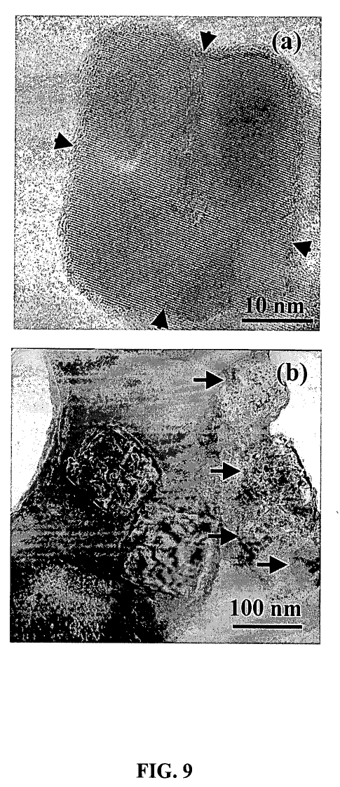

FIG. 9(a) is a high resolution TEM (HRTEM) image of a nanocube, in which the clear lattice fringes further confirm that the nanocubes are single crystals. The interplanar spacing is 3.25 Å, corresponding to the {111} planes of the diamond-type Ge. The chemical composition of the as-prepared nanocubes was analyzed by energy dispersive X-ray spectroscopy (EDS). FIG. 9(b) shows the EDS, indicating that the as-prepared nanocubes are pure Ge, since the Cu and C peaks come from the copper grid and carbon film support, respectively.

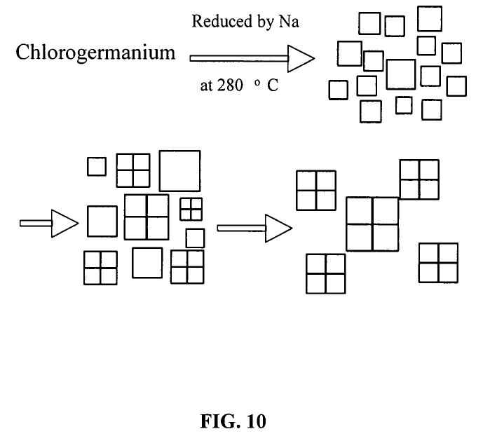

In order to understand the growth mechanism of the nanocubes, the structure of the as-prepared nanocubes was further investigated by HRTEM. FIG. 9(a) is an HRTEM image of a Ge nanocube, indicating that this nanocube is probably formed of four smaller nanocubes (indicated by arrows) that grows separately first and then form a big nanocube. FIG. 9(b) shows a low magnification TEM image of the nanocubes, in which the contrast of some nanocubes (indicated by arrows) changed and the surfaces of these nanocubes began to melt under electron beam irradiation for an extended period of time. The contrast change in the micrographs across the nanoparticles is likely due to changes of surface morphology. The melting of the surface and changes of the particle surface morphology of small nanocubes are favorable to the formation of big crystalline nanocubes when these small nanocubes aggregate together. Based on the above investigations, the following growth mechanism for the nanocube formation is proposed. First, during the reduction process, chlorogermaniums are reduced to small size cubic Ge nanocrystals. The small cubic particles aggregate together through assistance of the surfactant C₁₂E₇, which serves as a cohesive agent in aggregating process. Finally, these aggregated cubic particles grow into nanocubes with the crystallinity improved. FIG. 10 is a scheme that illustrates the growth process of the nanocubes.

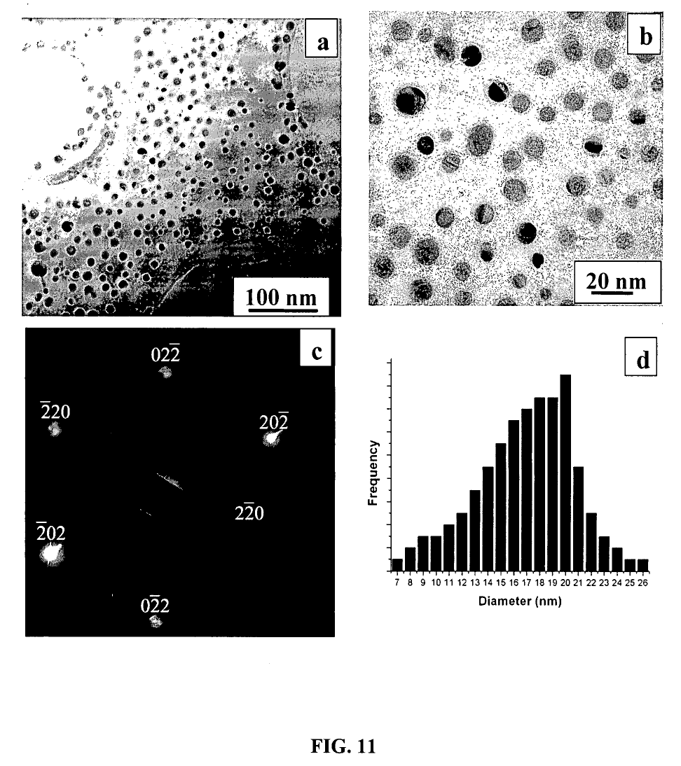

FIG. 11 shows XRD diffraction patterns of as-prepared Ge nanocrystals, indicating a clear signature of pure diamond phase Ge. FIG. 11(a) represents Ge nanocrystals prepared using surfactant C₁₂E₅ (high concentration) as a capping agent. FIG. 11(b) represents Ge nanocrystals prepared using surfactant C₁₂E₅ (low concentration) as a capping agent. FIG. 11(c) represents Ge nanocrystals prepared using surfactant C₁₂E₇ (high concentration) as a capping agent. FIG. 11(d) shows a diameter distribution histogram of the Ge nanocrystals.

The methods of the presently disclosed embodiments are advantageous in that they do not require expensive apparatus or complex purification and separation techniques, and are readily reproducible with high yield (e.g., gram quantity) of single crystal germanium nanocrystals. The methods utilize growth conditions that are milder than currently known synthetic methods for single crystal semiconducting nanocrystals. The inverse micelle solvothermal process of the presently disclosed embodiments which use non-aqueous conditions and specific surfactant types and surfactant ratios, produces single crystal nanocrystals that are homogeneous in size, and eliminates the need for using large excess of the reducing agent, and post-reaction purification and size separation. Highly crystalline ordered single-crystal nanocrystals may be prepared directly without further thermal treatment, which is usually needed by currently known methods to promote crystallization of group IV semiconducting nanoparticles, such as Si and Ge.

The methods of the presently disclosed embodiments may be utilized in commercial applications in industrial production of ordered single crystal Ge and Si nanocrystals, and other semiconducting nanocrystals such as PbTe, PbSe, Bi₂Te₃, and Bi₂Se₃, and similar structures, and their subsequent processing and integrating into practical working devices such as diodes, transistors, photoluminescence devices, electronics and optoelectronics. Ordered single-crystalline metal nanocrystals as produced by the methods, having a small domain size such as between about 1 nm and about 8 nm, may take advantage of the high surface area to volume ratio and to have utility as catalysts, precursors for thin films, show quantum size effects as evidenced by atomistic, non-bulk electronic or physical properties being evident in the particles as non-bulk, such as energy band gap, photoluminescence or melting properties, to have utility as single electron devices, sensors, biomedical markers, and in the case of radioactive metals, higher radiative flux fission sources.

The synthesis of ordered single-crystalline nanocrystals comprising semiconducting material and their analysis are described in the following examples, which are not intended to be limiting in any way.

### EXAMPLES AND METHODS

### Example 1

### Preparation of Single-Crystal Germanium Nanocrystals

The preparation of single crystal Ge nanocrystals was performed in a 125 mL Parr reactor (model 4750, Parr Company, Moline, Ill.). A typical preparation procedure of Ge nanocrystals is as follows: 80 mL hexane, 0.6 mL GeCl₄, 0.6 mL phenyl-GeCl₃, 1.8 mL C₁₂E₅, and 5.6 mL Na (25 wt % dispersion in toluene) were added to a 200-mL flask. The mixtures were stirred in a magnetic stirrer for 30 minutes before being transferred to a Parr reactor. The Parr reactor was kept at 280° C. for 72 h in a furnace, and then cooled to room temperature. A black powder was collected and washed with excess amounts of hexane, alcohol, and distilled water to remove NaCl byproduct and hydrocarbon residue, and then dried at 60° C. for 12 h in an oven.

### Example 2

### X-Ray Diffraction (XRD) Spectrum of Germanium Nanocrystals

The X-ray diffraction (XRD) spectrum of the prepared Ge nanocrystals shown in FIG. 1. The Ge lattice constant obtained by refinement the XRD data of the nanocrystals is a=5.648 Å, which is consistent with that of the bulk Ge. (JCPDS No. 4-545, Fd3m, a=5.657 Å)

### Example 3

### Preparation of Single-Crystal Germanium Nanospheres

The preparation of Ge spherical nanocrystals was performed in a 125 mL Parr reactor (model 4750, Parr Company, Moline, Ill.). A typical preparation procedure of Ge nanospheres is as follows: 80 mL hexane, 0.6 mL GeCl₄, 0.6 mL phenyl-GeCl₃, 0.6 mL pentaethylene glycol monododecyl ether (Cl₂E₅), and 5.6 mL Na (25 wt % dispersion in toluene) were added to a 200 mL flask. Then the mixtures were stirred in a magnetic stirrer for 30 min before being transferred to a Parr reactor. The Parr reactor was kept at 280° C. for 72 h in a furnace without any stirring and shaking and then cooled to room temperature. A black powder was collected and washed with excess amounts of hexane, alcohol, and distilled water to remove any NaCl byproduct and hydrocarbon residue, and then dried at 60° C. for 12 h in an oven.

### Example 4

### Preparation of Single-Crystal Germanium Nanocubes

The synthesis of Ge nanocubes was performed in a 125 mL Parr reactor (model 4750, Parr Company, Moline, Ill.). A typical synthesis procedure of Ge nanocubes is as follows: similar to the synthesis of Ge nanocrystals, 80 mL hexane, 0.6 mL GeCl₄, 0.6 mL phenyl-GeCl₃, 1.8 mL C₁₂E₇, and 5.6 mL Na (25 wt % dispersion in toluene) were added to a 200 mL flask. The mixtures were stirred in a magnetic stirrer for 30 minutes before being transferred to a Parr reactor. The Parr reactor was kept at 280° C. for 72 h in a furnace without any stirring and shaking and then cooled to room temperature. A black powder was collected and washed with excess amounts of hexane, alcohol, and distilled water to remove any NaCl byproduct and hydrocarbon residue, and then dried at 60° C. for 12 h in an oven. X-ray diffraction (XRD) and transmission electron microscope (TEM) were used to characterize the nanocubes.

All patents, patent applications, and published references cited herein are hereby incorporated by reference in their entirety. It will be appreciated that various of the above-disclosed and other features and functions, or alternatives thereof, may be desirably combined into many other different systems or applications. Various presently unforeseen or unanticipated alternatives, modifications, variations, or improvements therein may be subsequently made by those skilled in the art which are also intended to be encompassed by the following claims.

What is claimed is:

1. A process for forming single-crystal metal nanocrystals comprising:
suspending a metallic salt material having a plurality of metal ions in a non-aqueous inverse micelle solvent comprising at least one surfactant and at least one reducing agent; and
reducing the plurality of metal ions in the metallic salt material to form the single-crystal metal nanocrystals.

2. The process of claim 1 wherein the plurality of metal ions are selected from the group consisting of germanium, gallium, indium, silicon, neodymium, gadolinium, tellurium and neptunium.

3. The process of claim 1 wherein the reducing agent is selected from the group consisting of hydrogen gas, sodium metal, zinc metal, magnesium metal, aluminum metal, lithium aluminum hydride, sodium borohydride, and hydrazine.

4. The process of claim 1 wherein the single-crystal metal nanocrystals are used in an optoelectronic device, an electronic device, a photoluminescence device, a diode or a transistor.

5. A process for forming single-crystal metal nanocrystals comprising:
suspending an organometallic compound comprising a metallic material having a plurality of a metal ions in a non-aqueous inverse micelle solvent comprising at least one surfactant and at least one reducing agent; and
reducing the plurality of metal ions in the metallic salt material to form the single-crystal metal nanocrystals.

6. The process of claim 5 wherein the plurality of a metal ions is selected from the group consisting of germanium, gallium, indium, silicon, neodymium, gadolinium, tellurium and neptunium.

7. The process of claim 5 wherein the reducing agent is selected from the group consisting of hydrogen gas, sodium metal, zinc metal, magnesium metal, aluminum metal, lithium aluminum hydride, sodium borohydride, and hydrazine.

8. The process of claim 5 wherein the single-crystal metal nanocrystals are used in an electronic device.

9. A process for forming single-crystal germanium nanocrystals comprising:
suspending a germanium salt material or an organometallic germanium compound having a plurality of germanium ions in a non-aqueous inverse micelle solvent comprising at least one surfactant and at least one reducing agent; and
reducing the plurality of germanium ions to form the single-crystal germanium nanocrystals.

10. The process of claim 9 wherein the at least one reducing agent is selected from the group consisting of hydrogen gas, sodium metal, zinc metal, magnesium metal, aluminum metal, lithium aluminum hydride, sodium borohydride, and hydrazine.

11. The process of claim 9 wherein the single-crystal germanium nanocrystals are used in an optoelectronic device.

12. A single-crystal metal nanocrystal formed by a process comprising:
suspending a metallic salt material or an organometallic compound comprising a metallic material having a plurality of metal ions, in a non-aqueous inverse micelle solvent comprising at least one surfactant and at least one reducing agent; and
reducing the plurality of metal ions to form the single-crystal metal nanocrystal.

13. The single-crystal metal nanocrystal of claim 12 wherein the plurality of metal ions are selected from the group consisting of germanium, gallium, indium, silicon, neodymium, gadolinium, tellurium and neptunium.

14. The single-crystal metal nanocrystal of claim 12 wherein the reducing agent is selected from the group consisting of hydrogen gas, sodium metal, zinc metal, magnesium metal, aluminum metal, lithium aluminum hydride, sodium borohydride, and hydrazine.

15. The single-crystal metal nanocrystal of claim 12 used in a transistor.

16. An ordered single-crystal nanocube produced by a process comprising:
suspending a metallic salt material or an organometallic compound comprising a plurality of a metal salt molecules each having a metal ion, in a non-aqueous inverse micelle solvent comprising a surfactant heptaethylene glycol ether (C₁₂E₇) and at least one alkali metal reducing agent; and
reducing the plurality of metal ions to form the ordered single-crystal metal nanocube.

17. The ordered single-crystal nanocube produced by the process of claim 16 wherein the reducing agent is metallic sodium (Na).

18. An ordered single-crystal metal nanosphere produced by a process comprising:
suspending a metallic salt material or an organometallic compound comprising a metallic material comprising a plurality of a metal salt molecules each having a metal ion, in a non-aqueous inverse micelle solvent comprising a surfactant pentaethylene glycol ether (C₁₂E₅) and at least one alkali metal reducing agent; and
reducing the plurality of metal ions to form the ordered single-crystal metal nanosphere.

19. The ordered single-crystal metal nanosphere produced by the process of claim 18 wherein the reducing agent is metallic sodium (Na).

20. A nanocrystalline structure comprising a plurality of single-crystal germanium nanocrystals having a substantially homogeneous shape and a substantially uniform nanocrystal particle size.
